(19) United States
(12) Patent Application Publication
(10) Pub. No.: US 2024/0059964 A1
(43) Pub. Date: Feb. 22, 2024

(54) LANTHANIDE DOUBLE PEROVSKITE NANOCRYSTALS

(71) Applicant: BROWN UNIVERSITY, Providence, RI (US)

(72) Inventors: Ou Chen, Providence, RI (US); Peter Saghy, Providence, RI (US); Jerome R. Robinson, Providence, RI (US)

(21) Appl. No.: 18/451,325

(22) Filed: Aug. 17, 2023

Related U.S. Application Data
(60) Provisional application No. 63/398,561, filed on Aug. 17, 2022.

(51) Int. Cl. C09K 11/77; C01F 17/36

(52) U.S. Cl. CPC C09K 11/7773; C01F 17/36; C09K 11/7705; C09K 11/772; C09K 11/7733; C09K 11/7748; C09K 11/7757; C09K 11/7763; C01P 2002/34; C01P 2002/50; C01P 2002/72; C01P 2002/76; C01P 2002/77; C01P 2002/82; C01P 2004/04; C01P 2006/60; H10K 50/11

(57) ABSTRACT

Lanthanide double perovskite nanocrystals are described. The nanocrystals display high energy luminescence, making them useful in a variety of light-emitting materials and devices. Methods of preparing the lanthanide double perovskite nanocrystals using a hot injection method are also described.

### CROSS-REFERENCE TO RELATED APPLICATIONS

This application claims priority to U.S. Provisional Patent Application Ser. No. 63/398,561, filed Aug. 17, 2022, which is incorporated herein by reference.

### BACKGROUND

Lead halide perovskite nanocrystals (NCs) with a chemical formula of APbX₃ (A: Cs⁺ and methylammonium, and X: Cl⁻, Br⁻, or I⁻) have drawn an unprecedented amount of research and technological attention owing to their superior optical and optoelectronic properties. A. K. Jena, et al., Chem. Rev. 2019, 119, 3036. Despite extensive research efforts focusing on lead halide perovskites, their integration in potential applications has been severely burdened by lead-induced toxicity issues, raising significant environmental concerns. J. Li, et al., Nat. Commun. 2020, 11, 310. One potential solution is to exclude lead from the perovskite-based NCs through compositional substitution. C. I. Infante, et al., Nano Lett. 2021, 21, 6.

Substituting every two divalent lead cations with a pair of monovalent and trivalent metal cations results in a double perovskite (DP) crystal structure with a general formula of A₂M(I)M(III)X₆, which can serve as one important alternative of lead halide perovskites. Y. Liu, et al., Angew. Chem., Int. Ed. 2021, 60, 11592. Such a DP crystal structure with lead exclusion can effectively reduce toxicity of the materials while preserving the original 3D cubic perovskite crystal lattice. P. Su, et al., J. Phys. Chem. Lett. 2020, 11, 2812. While alkali metals or silver are the common choices for the monovalent M(I) cation site, large main group elements such as In, Sb, and Bi have been in the center of focus occupying the trivalent M(III) cation site. H. Tang, et al., Adv. Sci. 2021, 8, 2004118. Compared to the transition metals, these main group elements are relatively cost-effective, less toxic, and can satisfy the tolerance factor requirement of the 3D perovskite structure. L. Chu, et al., Nano-Micro Lett. 2019, 11, 16. Despite the lower toxicity, main group DP structures often suffer from unfavorable luminescence properties caused by their indirect bandgaps, necessitating further compositional tuning for practical applications. A. Bibi, et al., Mater. Today 2021, 49, 123.

Lanthanide (Ln; La—Lu) elements are generally considered non-toxic and can form large, air-stable trivalent Ln(III) cations. Even the rarest Lns are more abundant than the main group or transition metals frequently encountered in double perovskites (e.g., Ag, Bi, and In). S. Cotton, Lanthanide and Actinide Chemistry, 2nd ed., Wiley, New York 2006. Owing to the presence of f-electrons, these Ln cations display unique optical and magnetic properties including narrow emission peaks with high photoluminescence (PL) quantum yields (QYs), long spin coherence lifetimes, efficient light conversion through potential quantum cutting or upconversion processes, strong magnetic responses induced by unpaired f-electrons, and broad-band X-ray scintillation behaviors. S. L. Zuo, et al., Rare Met. 2020, 39, 1113. While main group elements usually only enable luminescence in or near the visible spectrum, Ln ions can display narrow emission peaks ranging from deep UV to IR. These properties make the Ln-containing materials ideal for a wide range of applications, such as light emitting diodes (LEDs) and lasers, optical/temperature sensors, X-ray scintillators, magnetic resonance imaging agents, and nano-Qbits. S. Jin, et al., Light: Sci. Appl. 2022, 11, 52. Ln-containing small molecules are frequently studied for the aforementioned purposes, but they are often only stable under inert conditions. For example, (NEt₄)³[LnCl₆] small molecules—close analogs of halide perovskites—cannot be handled in ambient air for even minutes due to being extremely hydroscopic. J. L. Ryan, et al., J. Phys. Chem. 1966, 70, 2845. Therefore, significant research efforts have been drawn to introducing Ln elements into perovskite bulk or nanomaterials, albeit mainly as low concentration doping components for either conventional APbX₃ perovskite lattices or A₂M(I)M(III)X₆ DP NCs. S. Jin, et al., Light: Sci. Appl. 2022, 11, 52.

Although bulk Ln-based DP (Ln-DP) phases have been known for decades (G. Rooh, et al., J. Cryst. Growth 2009, 311, 2470), their utility is limited by complicated high temperature synthesis (>900° C.) and insolubility inmost solvents except for water, which is detrimental to their crystal structure. The stability of Ln-DPs can be improved by fabricating nanomaterials surrounded by hydrophobic capping ligands. For example, the recently reported Cs₂NaErCl₆ DP NCs were found to be stable in ambient air for at least 1 month. R. Wu, et al., Laser Photonics Rev. 2021, 15, 2100218. The synthesized Cs₂NaErCl₆ DP NCs show near-IR (NIR) luminescence in the spectral range relevant for telecommunication. Accordingly, there remains a need for the development of additional Cs₂NaLnCl₆ DP NCs.

### SUMMARY OF THE INVENTION

The inventors have developed a method that enables the synthesis of lanthanide double perovskites on the nano scale, which are lanthanide-containing double perovskite nanocrystals. The nanomaterials can be dispersed in solvent to form colloidal solutions, thus enabling solution processibility for easy fabrication of devices compared to bulk materials. Many of the lanthanide double perovskites display superior optical properties. This includes deep-UV, visible, and near infrared fluorescence while being completely transparent (no absorption) in the visible range.

In one aspect, double perovskite nanocrystals represented by the formula Cs2ABX6 are provided, wherein: A is an alkali metal; B is one or more lanthanide selected from the group consisting of La, Ce, Pr, Nd, Sm, Eu, Gd, Tb, Dy, Ho, Er, Tm, and Yb; and X is a halide selected from Br, Cl, or I.

In another aspect, a light emitting material is provided, comprising a material comprising double perovskite nanocrystals represented by the formula Cs2ABX6, wherein: A is an alkali metal; B is one or more lanthanide selected from the group consisting of La, Ce, Pr, Nd, Sm, Eu, Gd, Tb, Dy, Ho, Er, Tm, and Yb; and X is a halide selected from Br, Cl, or I.

In another aspect, a light emitting device is provided, comprising a light emitting material comprising double perovskite nanocrystals represented by the formula Cs₂ABX₆, wherein: A is an alkali metal; B is one or more lanthanide selected from the group consisting of La, Ce, Pr, Nd, Sm, Eu, Gd, Tb, Dy, Ho, Er, Tm, and Yb; and X is a halide selected from Br, Cl, or I.

In another aspect, a method of preparing double perovskite nanocrystals represented by the formula Cs₂ABX₆ is provided, wherein: A is an alkali metal; B is one or more lanthanide selected from the group consisting of La, Ce, Pr, Nd, Sm, Eu, Gd, Tb, Dy, Ho, Er, Tm, and Yb; and X is a halide selected from Br, Cl, or I; comprising the steps of: 1) adding cesium salt, an alkali metal salt, and a lanthanide salt or acetylacetonate to a mixture of a non-polar organic solvent, oleic acid, and oleylamine; 2) degassing the mixture for about 30 minutes to about 2 hours at a temperature ranging from about 60° C. to about 120° C. to remove oxygen and water; 3) injecting chloromethylsilane at a temperature from about 150° C. to about 200° C.; 4) rapidly cooling the mixture to about room temperature; and 5) collecting double perovskite nanocrystals from the mixture.

### BRIEF DESCRIPTION OF THE FIGURES

FIGS. 1A-1D provide A) XRD patterns of Cs₂NaLnCl₆ DP NCs, where Ln=La (bottom) through Ln=Yb (top). Grey bars: reported peak positions of the Cs₂NaLaCl₆ and Cs₂NaYbCl₆ DP bulk materials. B) Zoomed-in XRD pattern for better visualization of the shift of (220) DP diffraction peak. C) XRD pattern of the Cs₂NaLaCl₆ DP NCs with the fitted cumulative curve (pink line), constituent fitted peaks (pink shades), and standard peak positions (grey bars). D) The linear relationship (R²=0.92) between the size of the Ln ion and the experimentally obtained lattice constants of the corresponding DP NCs.

FIGS. 2A-2L provide TEM images, size distribution histograms (insets), HR-TEM images (top right), and fast Fourier transform patterns (bottom right) of the six emissive Ln-DP NCs: A) Cs₂NaPrCl₆, B) Cs₂NaCeCl₆, C) Cs₂NaTbCl₆, D) Cs₂NaEuCl₆, E) Cs₂NaSmCl₆, and F) Cs₂NaYbCl₆. HR-TEM scale bars are 5 nm in each case. HR X-ray photoelectron spectroscopy (XPS) spectra of the six samples, confirming the presence of trivalent G) Pr, H) Ce, I) Tb, J) Eu, K) Sm, and L) Yb ions in the corresponding Cs₂NaLnCl₆ DP NCs. Note: XPS signals from divalent metal ions can be observed in the cases of the Eu-(J) and Yb (L)-based Ln-DP NCs due to X-ray radiation-induced reduction.

FIGS. 3A-3F provide graphs showing the A) Absorption spectra (black solid lines), PLE spectra monitored at the strongest PL peak (grey dashed lines), and PL spectra (colored solid lines with shading) of the six kinds of emissive Ln-DP NCs. B) Energy level diagrams indicating the expected luminescence from the six discussed Ln systems along with their assigned term symbols. Non-emissive levels omitted for clarity. C—F) PL lifetime decay plots (open circles) and fitted curve (solid lines) of the Cs₂NaCeCl₆ (C), Cs₂NaTbCl₆ (D), Cs₂NaEuCl₆ (E), and Cs₂NaYbCl₆ (F) DP NCs.

FIGS. 4A-4D provide graphs and schemes showing A) for the Ln-DP NCs displaying atomic f-d absorption features, the position of the first absorption peak correlates with the Ln^{III}/Ln^{IV} redox potential. The best fit line was used to estimate the absorption peak position of Cs₂NaNdCl₆ DP NCs to be around 7.3 eV. B) Orbital diagrams illustrating a typical atomic f-d transition event (left), and a schematic illustrating excitation and emission resembling direct bandgap transitions (right). C) For Ln-DP NCs showing LMCT features, the position of the first absorption peak correlates with the Ln^{II}/Ln^{III} redox potential. The fitting line was used to estimate the absorption peak position of Cs₂NaTmCl₆ DP NCs to be around 6.1 eV. D) Orbital diagrams illustrating a typical LMCT event (left), and a schematic illustrating excitation and emission resembling indirect bandgap transitions (right). Note: a hole transfer process is required for radiative f-f relaxation in this case.

FIGS. 5A-5F provide graphs showing the calculated band structures (left) and the corresponding DOSs (right) of the six emissive Ln-DP systems: A) Cs₂NaCeCl₆, B) Cs₂NaPrCl₆, C) Cs₂NaSmCl₆, D) Cs₂NaEuCl₆, E) Cs₂NaTbCl₆, and F) Cs₂NaYbCl₆. Spin down (blue solid lines) and spin up (purple solid lines) are differentiated in each case. The observed band gap transitions are marked with dashed arrows. Valence band maxima are set to 0 eV.

FIG. 6 provides a relative energy diagram of the highest occupied Cl 3p orbitals (blue pentagons), highest occupied Ln 4f orbitals (red triangles), lowest unoccupied Ln 4f orbitals (purple open squares), and lowest unoccupied Ln 5d orbitals (cyan open circles) across the Ln series. Horizontal grey lines indicate positions of Ln^{III} 4fⁿ excited states in Cs₂NaLnCl₆ bulk materials with the consideration of spin-orbit coupling. Note: high-energy calculated Ln^{III} 4fⁿ excited states are not included. Excited states of radioactive Pm are not included due to the lack of experimental data in DP systems. The expected lowest energy absorptions are indicated by pink arrows (f-d transitions) or blue arrows (LMCTs).

FIGS. 7A-7F provide graphs and diagrams A) energy level diagram illustrating the energy transfer from the Ce host to the Yb dopant bridged by the Tb component for Cs₂NaCe_{0.90}Tb_{0.09}Yb_{0.01}Cl₆ alloyed Ln-DP NCs. B) Absorption and PL spectra of the Cs₂NaCe_{0.90}Tb_{0.09}Yb_{0.01}Cl₆ alloyed Ln-DP NCs display emission from all three components under 340 nm excitation. C,D) 2D contour maps at visible (C) and NIR (D) regions for the Cs₂NaCe_{0.90}Tb_{0.09}Yb_{0.01}Cl₆ DP NCs, showing an excitation-dependent PL feature of the sample. E) Energy level diagram illustrating the energy transfer occurs from the Pr host to the Ce component of the Cs₂NaCe_{0.99}Ce_{0.01}Cl₆ alloyed Ln-DP NCs. F) Absorption and PL spectra of the Cs₂NaCe_{0.99}Ce_{0.01}Cl₆ DP NCs, displaying broadband UV-C to visible-blue emission.

### DETAILED DESCRIPTION OF THE INVENTION

The present invention provides lanthanide double perovskite nanocrystals. The nanocrystals display high energy luminescence, making them useful in a variety of light-emitting materials and devices. Methods of preparing the lanthanide double perovskite nanocrystals using a hot injection method are also provided.

### Definitions

The terminology as set forth herein is for description of the embodiments only and should not be construed as limiting of the invention as a whole. Unless otherwise specified, “a,” “an,” “the,” and “at least one” are used interchangeably. Furthermore, as used in the description of the invention and the appended claims, the singular forms “a”, “an”, and “the” are inclusive of their plural forms, unless contraindicated by the context surrounding such.

Also herein, the recitations of numerical ranges by endpoints include all numbers subsumed within that range (e.g., 1 to 5 includes 1, 1.5, 2, 2.75, 3, 3.80, 4, 5, etc.).

As used herein, the term “about” refers to +/−10% deviation from the basic value.

Unless defined otherwise, all technical and scientific terms used herein have the same meaning as commonly understood by one of ordinary skill in the art to which this invention belongs.

### Double Perovskite Nanocrystals

In one aspect, the present invention provides double perovskite nanocrystals represented by the formula Cs₂ABX₆, wherein: A is an alkali metal; B is one or more lanthanide selected from the group consisting of La, Ce, Pr, Nd, Sm, Eu, Gd, Tb, Dy, Ho, Er, Tm, and Yb; and X is a halide (i.e., a halogen bearing a negative charge) selected from Br, Cl, or I. In some embodiments, the alkali metal is Na, while in further embodiments X is Br or Cl, or Cl. A perovskite is any material with a crystal structure following the formula ABX₃. The nanocrystals can also be referred to as lanthanide double perovskite nanocrystals. Cs of the formula refers to the alkali metal cesium.

Alkali metals include lithium, sodium, potassium, rubidium, cesium, and francium. It is preferable to avoid the use of francium, which is significantly radioactive. In some embodiments, the alkali metals can be replaced with organic ions like methylammonium cation and formamidium cation. Similarly silver cations can be used, as long as the silver is monovalent.

The term “nanocrystal” and the like refer, in the usual and customary sense, to a polycrystalline material having a crystallite size (e.g., edge length) less than a micrometer (e.g., 1-10, 1-20, 1-30, 1-40, 1-50, 1-100, 1-200-, or even 1-500 nm). In some embodiments, the nanocrystals have a cuboid morphology and an edge length from about 5 to about 20 nm, from about 5 to about 15 nm, or from about 7.5 to about 15 nm.

### Light Emitting Material

Another aspect of the invention provides a light emitting material comprising a material comprising double perovskite nanocrystals represented by the formula Cs₂ABX₆, wherein: A is an alkali metal; B is one or more lanthanide selected from the group consisting of La, Ce, Pr, Nd, Sm, Eu, Gd, Tb, Dy, Ho, Er, Tm, and Yb; and X is a halide selected from Br, Cl, or I. Preferably, the material luminesces at a wavelength ranging from 260 to 1550 nm.

Examples of a light emitting material include a semiconductor material or a high energy x-ray or gamma-ray scintillator. Semiconductor materials are nominally small band gap insulators, and the most commonly used semiconductor materials are crystalline inorganic solids. In many cases, and as shown in the art, the conductivity or light emission efficiency of semiconductor material can be improved by doping, i.e., by adding an impurity element.

Scintillators are materials that are able to convert high energy radiation such as X-rays or gamma-rays to a near visible or visible light. They are widely used as detectors in medical diagnostics, high energy physics and geophysical exploration. Scintillators can be gaseous, liquid or solid, organic or inorganic (glass, single crystal, ceramics). Detectors based on scintillators are essentially composed of a scintillator material, and a photodetector that can be either a photomultiplier tube (PMT) or a photodiode. The role of the photodetector is to convert the outcoming light of the scintillator to an electrical signal.

The cerium and praseodymium materials emit UV light, making them useful for the fabrication of UV LEDs. The terbium, europium and ytterbium materials absorb high-energy UV light, and down-convert it to visible light, making them ideal for many applications.

In some embodiments, the lanthanide (“B”) is Pr, and the material has a peak emission from about 260 nm to about 270 nm. In other embodiments, B is Tb, and the material has a peak emission from about 540 nm to about 560 nm. In additional embodiments, B is Sm, and the material has a peak emission from about 590 nm to about 610 nm. In a further embodiment, B is Yb, and the material has a peak emission from about 990 nm to about 1000 nm. In a yet further embodiment, B is Eu, and the material has a peak emission from about 600 nm to about 620 nm.

The Praseodymium material displays the highest energy luminescence currently known for a perovskite material, enabling the fabrication of higher energy LEDs than any other similar material. The Terbium, Europium and Ytterbium materials are ideal for luminescent solar concentrators. They absorb UV light and down-convert it to visible or near-IR light that commercial solar cells can utilize better than UV light. They also do not absorb visible light, making them completely transparent.

### Light Emitting Devices

An additional aspect of the invention provides a light emitting device comprising a light emitting material comprising double perovskite nanocrystals represented by the formula Cs₂ABX₆, wherein: A is an alkali metal; B is one or more lanthanide selected from the group consisting of La, Ce, Pr, Nd, Sm, Eu, Gd, Tb, Dy, Ho, Er, Tm, and Yb; and X is a halide selected from Br, Cl, or I.

Examples of light emitting devices including a light emitting material comprising double perovskite nanocrystals include solar cells, luminescent solar concentrators, photocatalysts, fluorescence imaging probes, displays, solid-state lighting, and UV-protecting window coatings.

In some embodiments, the device is a light emitting diode. Non-limiting examples of electronic, optic-, or optoelectronic devices include a light emitting diode (LED) such as white LED, display device, light detector, X-ray detector, gamma-ray detector, and imaging detector such as a medical imaging detector.

An LED is a semiconductor light source that emits light when current flows through it. Electrons in the semiconductor recombine with electron holes, releasing energy in the form of photons. The color of the light (corresponding to the energy of the photons) is determined by the energy required for electrons to cross the band gap of the semiconductor. Due to their high photoluminescence quantum efficiencies, double perovskite nanocrystals are useful in light-emitting diodes (LEDs)

A display device is an output device for presentation of information in visual or tactile form. When the input information that is supplied has an electrical signal the display is called an electronic display.

A light detector is a device used in an optical transmission system to detect an optical signal generated by a light source and propagating through a medium. A light detector essentially is an optical receiver that is paired with an optical transmitter, both of which are connected to electrically based devices or systems. So, the source converts electrons to photons and the detector converts photons to electrons. Different types of light detectors include light dependent resistors (LDRs), photo diodes, photo transistors, and the like, and they are called photoelectric devices since they convert light energy to electric energy. The light detectors can detect different types of light such as visible light, ultraviolet light, infrared light, and the like.

X-ray detectors are devices used to measure the flux, spatial distribution, spectrum, and/or other properties of x-rays. Some of the common x-ray detectors include proportional counters, microchannel plates, and semiconductor detectors.

Gamma-ray detectors measure electromagnetic radiation through the process of the counting and measuring the energy of individual photons emitted from elements. Different types of detectors are used for detecting gamma rays, the most common are scintillation detectors and semiconductors.

Imaging detector (also referred to as image sensor or imager) is a sensor that detects and conveys information used to make an image by converting variable attenuation of light waves (as they pass through or reflect off objects) into signals, small bursts of current that convey the information. Imaging detectors, such as x-ray detectors, can be used in medical imaging equipment.

In other embodiments the device is a solar concentrator. A luminescent solar concentrator is a device for concentrating radiation, solar radiation in particular, to produce electricity. Luminescent solar concentrators operate on the principle of collecting radiation over a large area, converting it by luminescence (specifically by fluorescence) and directing the generated radiation into a relatively small output target. Double perovskite nanocrystals can be used for photovoltaic cells such as those used in solar concentrators or collectors. Perovskite cells possess many optoelectrical properties that benefit their use in solar cells. Min et al., Nature. 598 (7881): 444-450 (2021).

In a further embodiment, the device is a laser. Double perovskite nanocrystals can be used to generate laser light. A laser is a device that emits light through a process of optical amplification based on the stimulated emission of electromagnetic radiation. A laser differs from other sources of light in that it emits light that is coherent, both spatially and temporally

Lasers are used in optical disc drives, laser printers, barcode scanners, DNA sequencing instruments, fiber-optic, and free-space optical communication, semiconducting chip manufacturing (photolithography), laser surgery and skin treatments, cutting and welding materials, and a wide range of other applications. Perovskite nanocrystal semiconductors can be used for highly efficient two-photon absorption in laser designs. Xu et al., J. Am. Chem. Soc., 138, 11, 3761 (2016).

Lanthanide double perovskite nanocrystals are colloidal nanocrystals. This enables easy utilization and integration in device fabrication, which is not possible using bulk materials. The perovskite nanomaterials developed by the inventors can readily be dispersed in different solvents without structural change, which is important for the aforementioned applications and processing. Bulk materials, on the other hand either, do not disperse at all in organic solvents, or they do so without maintaining their crystalline integrity—both of which are highly undesirable.

### Methods for Preparing Lanthanide Double Perovskite Nanocrystals

The inventors have prepared lanthanide double perovskite nanocrystals using a colloidal hot-injection method, which involves the injection of a “cold” (i.e., room temperature) solution of chlorotrimethylsilane into a hot liquid containing the metal cations and organic ligands, leading to the formation of lanthanide double perovskite nanocrystals.

Accordingly, a further aspect of the invention provides a method of preparing double perovskite nanocrystals represented by the formula Cs₂ABX₆, wherein: A is an alkali metal; B is a lanthanide selected from the group consisting of La, Ce, Pr, Nd, Sm, Eu, Gd, Tb, Dy, Ho, Er, Tm, and Yb; and X is a halide selected from Br, Cl, or I. The method includes the steps of: 1) adding cesium salt, an alkali metal salt, and a lanthanide salt or acetylacetonate to a mixture of a non-polar organic solvent, oleic acid, and oleylamine; 2) degassing the mixture for about 30 minutes to about 2 hours at a temperature ranging from about 60° C. to about 120° C. to remove oxygen and water; 3) injecting chloromethylsilane at a temperature from about 150° C. to about 200° C.; 4) rapidly cooling the mixture to about room temperature; and 5) collecting double perovskite nanocrystals from the mixture.

Examples of non-polar organic solvent include o-xylene, m-xylene, p-xylene, toluene, hexane, heptane, ethylbenzene, benzene, octadecene, and a combinations thereof. In particular embodiments such as those exemplified herein, the solvent is octadecene.

The method makes use of cesium salt, an alkali metal salt, and a lanthanide salt, each of which is independently an acetate, chloride, bromide, nitrate, mesylate, maleate, fumarate, tartrate, p-toluenesulfonate, benzenesulfonate, benzoate, phosphate, sulfate, citrate, carbonate, or succinate salt. In some embodiments, the cesium salt is carbonate. In further embodiments, the alkali metal salt is alkali metal acetate, and the lanthanide salt is lanthanide acetate.

The method encompasses reasonable variation in the time and temperature of reaction conditions. In some embodiments, the method comprises degassing the mixture for about 30 minutes to about 2 hours at a temperature ranging from about 60° C. to about 120° C. to remove oxygen and water. Generally, a higher temperature will result in a decreased reaction time. Accordingly, in some embodiments, the step of degassing the mixture is carried out for about one hour at about 110° C. Likewise, the method comprises injecting chloromethylsilane at a temperature from about 150° C. to about 200° C. However, in some embodiments, the chlormethylsilane is injected at a temperature from about 165° C. to about 190° C., while in further embodiments, the chloromethylsilane is injected at about 180° C.

Those skilled in the art will appreciate that other synthetic routes may be used to synthesize the compounds of the invention. Although specific starting materials and reagents are depicted in the reaction schemes and discussed below, other starting materials and reagents can be easily substituted to provide a variety of derivatives and/or reaction conditions. In addition, many of the compounds prepared by the methods described below can be further modified in light of this disclosure using conventional methods well known to those skilled in the art.

The present invention is illustrated by the following example. It is to be understood that the particular example, materials, amounts, and procedures are to be interpreted broadly in accordance with the scope and spirit of the invention as set forth herein.

### Example

### Lanthanide Double Perovskite Nanocrystals with Emissions Covering the UV-C to NIR Spectral Range

Herein, we present a versatile colloidal method for the synthesis of Cs₂NaLnCl₆ DP NCs for all Lns except for lutetium and promethium. The as-synthesized Ln-DP NCs (Ln=La—Nd, Sm— Yb) display uniform size and cubic shape with a pure DP crystal phase. In addition to the already reported Cs2NaErCl6 DP NCs, we found that six additional Ln-DP NCs (Ln=Ce, Pr, Sm, Eu, Tb, and Yb) exhibit characteristic emission features covering a wide spectral window from UV-C to NIR (i.e., 260-995 nm). In particular, the Cs₂NaPrCl₆ DP NCs display rarely accessible UVC emission with a PLQY of 14%, the highest QY value reported for any UV-C emitting perovskite NCs. The Cs₂NaTbCl₆ DP NCs show bright green emission with a PLQY of 45%, the highest value of any pure Ln-DP NCs known so far. By analyzing the optical behaviors of these materials with the aid of density functional theory (DFT) calculations, fundamental origins of the absorption and emission electronic transitions were identified and understood. Furthermore, taking advantage of high miscibility of different Lns, we have successfully demonstrated the possibility of fabricating alloyed Cs₂NaLnCl₆ DP NCs simultaneously containing multiple different Ln components. The resulting alloyed Ln-DP NCs possess optical properties that are inaccessible to the single Ln counterparts. Our study provides fundamental insight into electronic structure and optical properties of Ln-based perovskite materials, which will enable further development of Ln-DP NCs. The synthesized Ln-DP NCs are potentially suitable materials for a wide range of applications, including ultra-high energy LEDs, high-security anti-counterfeiting, efficient luminescent solar concentrators, as well as low-threshold lasers.

### Results and Discussion

### Synthesis, Morphology, and Crystal Phase of Ln-DP NCs

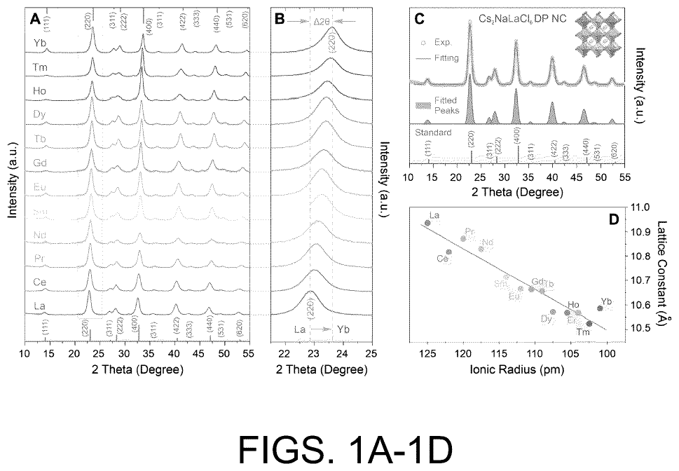

Ln-DP NCs were synthesized using a modified colloidal hot injection approach. C. Murray, et al., Annu. Rev. Mater. Sci. 2000, 30, 545. Briefly, cesium carbonate, sodium acetate, and Ln-acetate or acetylacetonate salts were added to a solution mixture of octadecene, oleic acid, and oleylamine. After oxygen and water were removed by degassing under vacuum for 1 hour at 110° C., the solution was heated to 180° C. Chlorotrimethylsilane was injected into the reaction solution, followed by rapid cooling to room temperature after 2 min. After purification, the obtained Ln-DP NCs can be redispersed in hexane to form a stable suspension. Powder X-ray diffraction (XRD) patterns of all the samples showed a cubic DP crystal phase (space group: Fm3m) with no indication of impurity presence (FIG. 1A). The position of the diffraction peaks shifted systematically to higher 20 angles moving down the Ln series (La to Yb), consistent with a monotonic shrinking trend of the crystal lattice (FIG. 1B). The corresponding lattice parameter (a) of each Ln-DP NCs can be quantitatively determined through fitting the XRD peaks (FIG. 1C), showing a decrease from 10.935 Å for Cs₂NaLaCl₆ NCs to 10.585 Å for Cs₂NaYbCl₆ NCs (FIG. 1D). The linear relationship between the calculated lattice parameter and the corresponding Ln^{III} cationic radius indicates that the lattice shrinkage is primarily a result of decreasing Ln^{III} size (FIG. 1D). Importantly, the synthesized Ln-DP NCs display excellent colloidal stability under N₂ or dry air, whereas negligible changes in the XRD patterns were observed for Ln-DP NC samples stored under dry air for at least 4 weeks.

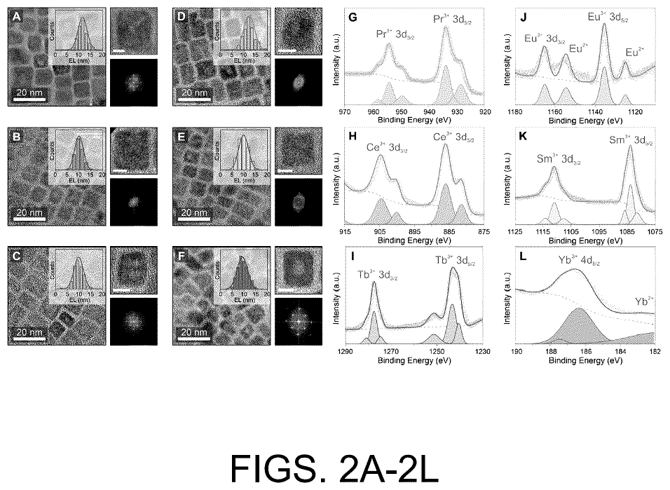

Transmission electron microscopy (TEM) measurements revealed a cuboidal morphology for the synthesized Ln-DP NCs (FIG. 2A-F), consistent with the cubic DP crystal phase and an isotropic NC growth fashion. Protesescu et al., Nano Lett. 2015, 15, 3692. The average edge lengths of the Ln-DP NCs ranged from 9.2 to 12.2 nm (FIG. 2A-F). High-resolution TEM (HR-TEM) images viewed along the double perovskite [100] direction, and their corresponding fourfold symmetric fast-Fourier transforms further supported the single crystalline nature of Cs2NaLnCl6 DP NCs (FIG. 2A-F). X-ray photoelectron spectroscopy (XPS) measurements established the presence of lanthanide ions in their trivalent oxidation state for each DP NC material (FIG. 2G-L). Additional signals for divalent Eu and Yb were observed, which can be attributed to reduction upon exposure to ionizing radiation (FIG. 2J, L), enabled by the easily accessible divalent state of europium and ytterbium. H. Nalumaga, et al., Mater. Res. Bull. 2022, 145, 111562. XPS survey scans were used to calculate atomic percentages in each material, which were in good agreement with the stoichiometry of the Cs₂NaLnCl₆ DPs. Altogether, our experimental results unambiguously establish the successful syntheses of Ln-DP NCs.

### Optical Properties of Ln-DP NCs

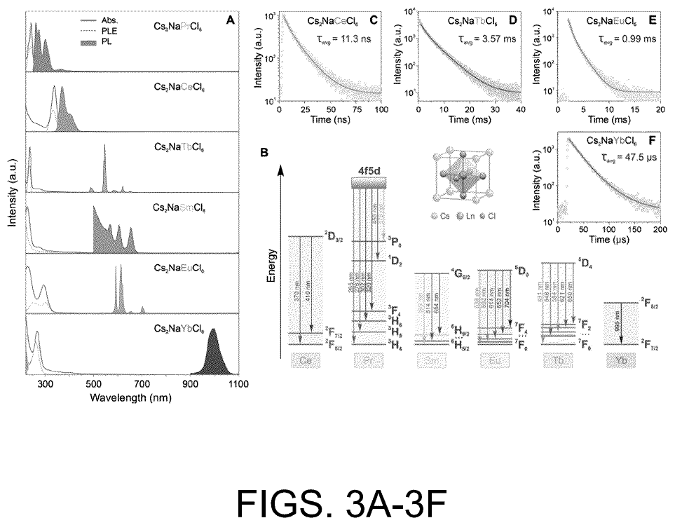

Six of the 12 newly synthesized Ln-DP NCs (i.e., Cs₂NaLnCl₆ DP NCs, Ln=Ce, Pr, Sm, Eu, Tb, and Yb) showed measurable emission with the PL peaks covering a wide spectral range from UV (Ln=Pr and Ce) through visible (Ln=Tb, Eu, and Sm) to NIR (Ln=Yb and the previously reported Er) (R. Wu, et al., Laser Photonics Rev. 2021, 15, 2100218) (FIG. 3A). Optical properties were found to be practically unchanged even after 4 weeks of storage in agreement with our observations by XRD.

Cs₂NaPrCl₆ DP NCs displayed the highest energy emission peaks of the Cs₂NaLnCl₆ DP NCs, with three major emission peaks observed at 265, 276, and 302 nm (4.68, 4.49, and 4.11 eV, respectively). Each of the emission peaks correspond to Pr-based electronic transitions from the 4f¹5d¹ excited state (term symbol ³H₄) to 4f² levels (term symbols ³H_{J}, where J=4-6) (FIG. 3A,B). X. Wang, et al., J. Mater. Chem. C 2022, 10, 3626. Perovskite-based materials emitting at the UV spectral region have been rarely reported in the literature, (Y. Zhang, et al., Angew. Chem., Int. Ed. 2021, 60, 9693) and more generally UV-emitting Pr³⁺ materials with reported PLQYs are rare. X. Wang, et al., Nat. Commun. 2020, 11, 2040. In the case of Cs₂NaPrCl₆ DP NCs, a relatively high PLQY of 14% in the UV-C region was measured, representing the brightest UV-C emitting perovskite NCs reported to date. A band gap of 4.92 eV was determined by a Tauc plot analysis based on the first narrow (full width at half maximum, FWHM=330 meV) absorption peak at 245 nm assuming a direct bandgap transition (see discussion below). PL excitation (PLE) spectra for all the major emission peaks well overlapped with the absorption profile of the sample, indicating the same energy origin of these emissive pathways. Despite extensive efforts, meaningful lifetime measurements of Cs₂NaPrCl₆ NCs were not possible due to the lack of a pulsed excitation source at sufficiently high energies. Access to UV-emitting, all-inorganic perovskites are highly desirable for optoelectronic applications, LED fabrications, and biological disinfecting applications. M. Shimizu, et al., Aggregate 2022, 3, e144.

Cs₂NaCeCl₆ DP NCs displayed UV-A/violet emission with a main peak at 370 nm (3.35 eV) and a shoulder at 410 nm (3.02 eV) (FIG. 3A), which can be respectively assigned to the ²D_{3/2}→²F_{5/2} and ²D_{3/2}→²F_{7/2} electronic transitions within [CeCl₆]³⁻ octahedral units (FIG. 3B). G. Pan, et al., Nano Lett. 2017, 17, 8005. A narrow (FWHM=270 meV) absorption peak centered at around 340 nm serves as the main excitation feature for both emission peaks, consistent with the observation for the [CeCl₆]³⁻ molecular anion, revealing a high degree of similarity to molecular analogues. J. L. Ryan, et al., J. Phys. Chem. 1966, 70, 2845. A direct bandgap of 3.52 eV was determined for the Cs₂NaCeCl₆ DP NCs based on the Tauc plot analysis of the absorption profile. Cs₂NaCeCl₆ DP NCs displayed a moderate PLQY of 6% and a PL lifetime of 11.3 ns (FIG. 3C). Such a short lifetime decay can be explained by the Laporte-allowed nature of the corresponding Ln 5d→4f transitions (i.e., ²D_{3/2}→²F_{5/2} and ²D_{3/2}→²F_{7/2}), in good agreement with the reported lifetime value for the emission of Ce³⁺ doped CsPbCl₃ perovskite NCs. G. Pan, et al., Nano Lett. 2017, 17, 8005.

Cs₂NaTbCl₆ DP NCs exhibited a strong green emission originating from the Tb ⁵D₄→⁷F_{J} (J=2-6) transitions, where the most intense peak was located at 550 nm (2.25 eV) (FIG. 3A,B). G. Pan, et al., Nano Lett. 2017, 17, 8005. The observed emissive transitions are sensitized by a strong sharp 4f→5d absorption feature at 238 nm (5.21 eV, FWHM=250 meV) as shown in the PLE spectrum (FIG. 3A), corresponding to a direct bandgap of 5.08 eV. Importantly, the Cs₂NaTbCl₆ DP NCs exhibited the highest PLQY of 45% of all the synthesized Ln-DP NCs in this study, and a long lifetime (3.57 ms) of the 5D4 excited state (FIG. 3D). The PL lifetime was found to be so long due to the spin-forbidden f-f relaxations involved in the emission process (i.e., ⁵D₄→⁷F_{J}, J=2-6). G. Pan, et al., Nano Lett. 2017, 17, 8005.

Cs₂NaSmCl₆ DP NCs possessed three extremely weak, yet characteristic emission peaks at 569 (2.18 eV), 607 (2.04 eV), and 655 nm (1.89 eV) (FIG. 3A), which can be assigned to the Sm ⁴G_{9/2}→⁶H_{J} (J=5/2, 7/2, 9/2) electronic transitions. G. Pan, et al., Nano Lett. 2017, 17, 8005. The peaks are sensitized by a single broad (FWHM=940 meV) absorption peak at 230 nm as shown in the absorption and PLE spectra (FIG. 3A), close to the UV cutoff of 220 nm imposed by double bonds in the oleic acid and oleylamine ligands. This absorption peak was significantly broader (FWHM=940 meV) than the f-d absorptions seen for the Pr, Ce, and Tb-based DP NCs, and thus it was identified as a ligand to metal charge transfer (LMCT) transition. J. L. Ryan, et al., J. Phys. Chem. 1966, 70, 2845. The PLQY and PL lifetime of the material could not be reliably measured due to the low PL signal intensity.

Cs₂NaEuCl₆ DP NCs emitted in the red part of the spectrum, with several narrow emission peaks located between 590-710 nm (FIG. 3A) that can be assigned to characteristic Eu^{III} electronic transitions associated with ⁵D₀→⁷F_{J} (J=0-4) states (FIG. 3A,B). G. Pan, et al., Nano Lett. 2017, 17, 8005. The main absorption feature observed at 295 nm was broad (FWHM=680 meV) and thus it was identified as a LMCT transition with an indirect bandgap of 3.61 eV. The PLQY of the sample was determined to be 1.5%, significantly lower than the Pr—, Ce—, and Tb-based DP NCs, likely caused by non-radiative relaxation related to Eu—Eu coupling, P. A. Hansen, et al., J. Lumin. 2019, 215, 116618 as well as the indirect nature of the bandgap (see discussion in the Absorption Features and Their Origins section). A PL lifetime of 0.99 ms was measured for the sample, expectedly long due to the spin-forbidden nature of the f-f relaxation pathways (FIG. 3E). J. L. Ryan, et al., J. Phys. Chem. 1966, 70, 2845. It is worth noting that no divalent europium species were observed in the as-synthesized Cs₂NaEuCl₆ DP NCs, evidenced by the lack of characteristic divalent f-d absorption and emission features.

Cs₂NaYbCl₆ DP NCs displayed a weak characteristic Yb ²F_{5/2}→²F_{7/2} emission at 995 nm (1.25 eV) (FIG. 3A), in line with the typical Yb-emission feature observed in other Yb-containing perovskite materials. G. Pan, et al., Nano Lett. 2017, 17, 8005. A broad (FWHM=570 meV) absorption peak at 260 nm was measured and identified as a LMCT transition, leading to an indirect bandgap of 4.12 eV according to the corresponding Tauc plot analysis. G. Pan, et al., Nano Lett. 2017, 17, 8005. The PL lifetime was measured to be 47.5 μs, which was about tenfold faster than that reported for Yb-doped CsPbCl₃ perovskite NCs (FIG. 3F). Cai et al., Adv. Sci. 2020, 7, 2001317. A low PLQY of ≈0.2% along with the fast PL lifetime decay both indicated the presence of significant Yb—Yb coupling induced PL quenching effect. Z. Wang, et al., J. Phys. Chem. C 2018, 122, 26298. Similar to the Cs₂NaEuCl₆ DP NCs, no presence of divalent ytterbium species were detected.

Absorption Features and their Origins

Due to the contracted nature of the 4f orbitals, lanthanides in the trivalent oxidation state display characteristic optical transitions that are often minimally perturbed by changes in ligand field. J. C. G. Bunzli, et al., Chem. Soc. Rev. 2005, 34, 1048. It is well established that emission from Ln^{III} materials requires effective sensitization; however, f-f absorption events—that are often the lowest energy electronic transitions—are ineffective in this regard due to their Laporte- and spin-forbidden nature (∈: 0.1-10 m⁻¹ cm⁻¹). B. G. Wybourne, et al., Optical Spectroscopy of Lanthanides: Magnetic and Hyperfine Interactions, Taylor and Francis, London 2007. Only Cs₂NaLnCl₆ DP NCs displaying pronounced absorption features emitted with considerable intensity, there-fore identification and assignment of their electronic absorption features are crucial to understanding and controlling their resulting optical properties. The six emissive Ln-DP NC samples (i.e., the Cs₂NaLnCl₆ NCs with Ln=Ce, Pr, Sm, Eu, Tb, and Yb) can be divided into two groups depending on the nature of their absorption features: i) narrow atomic f-d absorption for the Pr—, Ce—, and Tb-based Ln-DP NCs; and ii) broad Cl-to-Ln LMCT absorption for the Eu—, Sm-, and Yb-containing ones. J. L. Ryan, et al., J. Phys. Chem. 1966, 70, 2845. The absorption features observed in Ln-DP NCs are very close in energy to the absorption features of corresponding molecular analogs, and they show minimal quantum confinement effects because of the highly localized valence orbitals. A similar lack of dimensional confinement was previously described for Bi-based layered DPs. M. Pantaler, et al., JACS Au 2021, 2, 136.

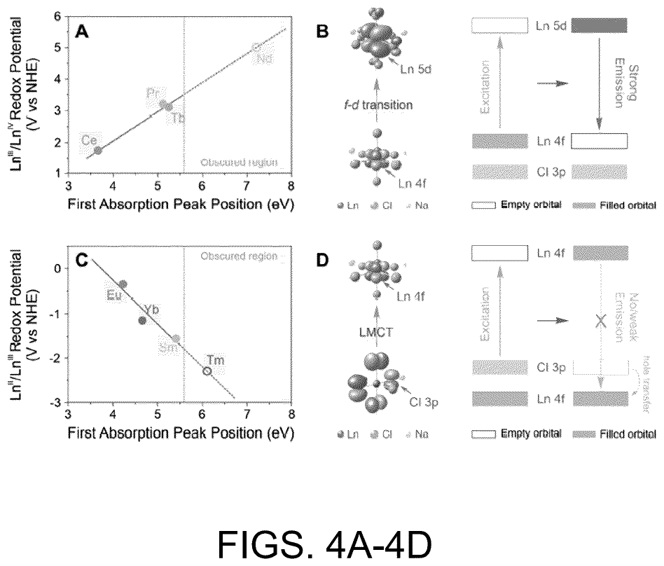

In the case of f-d absorptions, a 4f-electron is promoted to a high energy unoccupied 5d-orbital, representing a direct transition with negligible spatial charge separation (FIG. 4A,B). This Laporte- and spin-allowed transition is typically narrower (approximately two to threefold) than charge-transfer transitions (e.g., LMCT), (J. L. Ryan, K. C. Jorgensen, J. Phys. Chem. 1966, 70, 2845) and the energy of the transition blue shifts with increasing Ln^{III/IV} reduction potentials. Consistent with these expectations, the first absorption transitions of Cs₂NaLnCl₆ DP NCs (Ln=Ce, Pr, and Tb) were relatively narrow (FWHM of about 300 meV in each case), while the energy of the transitions displayed a linear correlation with the corresponding Ln^{III/IV} couple (E_{1/2}=+1.7 to +3.2 V vs NHE, FIG. 4A). L. J. Nugent, et al., J. Inorg. Nucl. Chem. 1971, 33, 2503. Based on this correlation, the Ln with the next most accessible tetravalent state, Nd^{III} (E_{1/2}=+5 V vs NHE), would be predicted to display a 4f-5d absorption feature around ≈170 nm (≈7.3 eV). L. J. Nugent, et al., J. Inorg. Nucl. Chem. 1971, 33, 2503. This transition falls well outside of the measurable spectral region into the deep UV, and was consistent with the effectively featureless absorption and emission profile for Cs₂NaNdCl₆ DP NCs (FIG. 4A).

In the case of Cl 3p to Ln 4f LMCT absorption events, an electron is promoted from a filled Cl 3p-orbital to an empty Ln 4f-orbital to generate a transient charge-separated species featuring a divalent Ln^{II} ion and a hole on one of the Cl ligands (FIG. 4D). Similar divalent Ln species have been identified and detected previously in Ln-doped CsPbCl₃ perovskite NCs using transient absorption techniques. W. J. Chang, et al., J. Phys. Chem. C 2021, 125, 25634. Molecular [LnCl₆]³⁻ (Ln=Sm^{III}, Eu^{III}, Tm^{III}, and Yb^{III}) display strong, broad LMCT transitions which red shift with increasing Ln^{II/III} reduction potentials. Cs₂NaLnCl₆ DP NCs (Ln=Sm, Eu, and Yb) displayed strong, broad LMCT absorption features (FWHM=570-940 meV), where the energy of the first transition showed a linear correlation with the corresponding Ln^{II/III} redox potential (FIG. 4C; E_{1/2}=−0.35 to −1.55 V vs NHE). L. J. Nugent, et al., J. Inorg. Nucl. Chem. 1971, 33, 2503. Based on this correlation, the Ln with the next most accessible divalent state, Tm^{III} (E_{1/2}=−2.3 V vs NHE), would be predicted to display a LMCT absorption feature around ≈205 nm. The position of this transition would not be directly observable due to spectral overlap with solvent and ligand absorptions, consistent with the effectively featureless absorption and emission profile for Cs₂NaTmCl₆ DP NCs (FIG. 4C).

Analogies of the electronic transitions can also be drawn to the extended nanocrystalline solids for their absorptive bandgap transitions. Like direct bandgap transitions, atomic f-d transitions keep the excited electron and the hole localized on the same atom upon excitation, enabling direct radiative recombination without spatial separation (FIG. 4B). In contrast, LMCT transitions lead to the transfer of the excited electron from the ligand to the metal center, resulting in a spatial separation of the electron and the hole in the excited state as seen for indirect bandgap transitions. Charge-separated excited states involved in this LMCT process can only be emissive following a hole transfer step from Cl 3p- to Ln 4f-orbitals (FIG. 4D). M. Zeng, et al., ACS Appl. Nano Mater. 2020. However, due to the slow hole transfer process (few ns, multiple orders of magnitude slower than the electron transfer process depending on the energy difference), the energy of charge separated excited states is more likely dissipated through non-radiative pathways such as phonon-assisted energy transfer, or transferred to dark sites prior to luminescence. S. Mei, et al., Adv. Sci. 2021, 8, 2003325. Consequently, the PLQYs for the materials with atomic f-d transitions are expected to be higher than those with LMCT transitions. A trend consistent with these explanations was observed for Cs₂NaLnCl₆ DP NCs; DP NCs with direct bandgap absorptions (i.e., 4f-5d transitions; Ce, Pr, Tb) displayed dramatically higher PLQYs than those with indirect bandgap absorptions (i.e., LMCT transitions; Sm, Eu, and Yb) (FIG. 4). These findings were also consistent with the observed photophysical behavior of Cs₂NaErCl₆ DP NCs and their Sb^{III}- and Bi^{III}-doped derivatives. The UV-vis spectrum of Cs₂NaErCl₆ DP NC lack strong absorption features capable of sensitization, which leads to low PLQY. Sb^{III}- and Bi^{III}-doping introduces strong, Laporte- and spin-allowed Sb and Bi-based absorption transitions, which increased the PL intensity dramatically. R. Wu, et al., Laser Photonics Rev. 2021, 15, 2100218.

### Computational Analysis

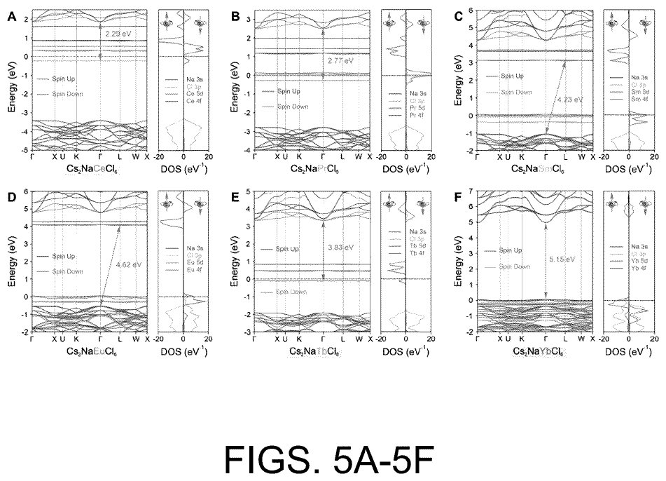

To gain a deeper understanding of the electronic structures of Cs₂NaLnCl₆ DPs, DFT (P. Kratzer, et al., Front. Chem. 2019, 7, 106) calculations were employed. Band structures and density of states (DOS) DFT calculations for the six emissive materials (i.e., Cs₂NaLnCl₆ with Ln=Ce, Pr, Sm, Eu, Tb, and Yb) were carried out using the common plane wave approach, (M. Topsakal, et al., Comput. Mater. Sci. 2014, 95, 263) employing the Perdew-Burke-Ernzerhof (PBE, generalized gradient approximation) (J. P. Perdew, et al., Phys. Rev. Lett. 1996, 77, 3865) functional with non-linear core corrections and scalar relativistic effects. Calculated lattice constants of the six selected Cs₂NaLnCl₆ were in good agreement with reported values, with computed values being systematically overestimated by ≈0.2 Å. G. Meyer, Prog. Solid State Chem. 1982, 14, 141. Across all these six systems, the valence band maximum was dominated by Cl 3p character with varying contributions from Ln 4f-orbitals, while the conduction band minimum is primarily composed of Ln 4f and 5d orbitals (FIG. 5), in agreement with experimental findings using Ln-DP bulk solids (P. A. Tanner, et al., Spectrosc. Lett. 2010, 43, 431), albeit with significant differences in the relative energies of the spin polarized 4f states.

Calculations for the Ce, Pr, and Tb Cs₂NaLnCl₆ DP NCs successfully predicted energetically accessible, direct bandgap transitions corresponding to Laporte- and spin-allowed Ln-centered 4f→5d transitions at 2.29, 2.77, and 3.83 eV (FIG. 5A,B,E). While the calculated transition energies were systematically underestimated by ≈1.2 eV from the experimentally determined direct bandgaps (3.52, 4.92, and 5.08 eV), the trend in their relative energies was successfully reproduced within the series. Calculations of Sm and Eu Cs₂NaLnCl₆ DP NCs (FIG. 5C,D) also successfully predicted energetically accessible, indirect bandgap transitions corresponding to LMCT Cl 3p→Ln 4f transitions (Smcalc: 4.23 eV, Smexpt: 4.71 eV; Eucalc: 4.62 eV, Euexpt: 3.61 eV). In contrast, calculations of Cs₂NaYbCl₆ DP NCs predicted a direct bandgap transition corresponding to a high-energy (5.15 eV), parity-allowed Ln 4f→5d transition, instead of an indirect bandgap transition originating from a LMCT Cl 3p→Ln 4f transition observed in our experiments and prior literature reports (FIG. 5F).

While our plane-wave calculations reproduced some general properties of Cs₂NaLnCl₆ DP NCs, they incorrectly predicted the nature of the bandgap for Yb and featured relatively large energy differences for calculated and experimental bandgap transitions within the series. Due to the highly correlated nature of 4f states, the band structures of Ln-containing materials can be non-trivial to reproduce by single determinant methods. M. Ferbinteanu, et al., Inorg. Chem. 2017, 56, 9474. While multi-configurational approaches, such as complete active space self-consistent field, can be used to model multi-reference character, these methods scale poorly with active space size and can be cost-prohibitive for large active spaces. P. G. Szalay, et al., Chem. Rev. 2012, 112, 108. Given these restrictions, and the striking similarities in the optical properties of Cs₂NaLnCl₆ DPs NCs and [LnCl₆]³⁻ molecular analogs, we also interrogated the electronic structure of previously studied small molecule models, [Na₆LnCl₆]³⁺ (Ln=Ce—Yb), by DFT. D. Aravena, et al., Inorg. Chem. 2016, 55, 4457. All calculations were carried out using the hybrid PBE functional and property-optimized def2-tzvpp(d) basis sets for Ln reported by Rappoport. D. Rappoport, J. Chem. Phys. 2021, 155, 124102. Geometry-optimized structures of [Na₆LnCl₆]³⁺ were in good agreement with the crystal structures of Cs₂NaLnCl₆, where calculated and experimentally determined Ln-Cl bond distances were within 0.04 Å of one another. Energies of the highest occupied Cl 3p and Ln 4f orbitals as well as the lowest unoccupied Ln 4f and 5d orbitals (Ln=Ce—Yb) were calculated in the ground state, but this simple model was also insufficient to correctly predict the nature of observed absorption features. However, time-dependent DFT (TD-DFT) calculations carried out on the optimized structures of [Na₆LnCl₆]³⁺ at the same level of theory effectively captured the main sensitization transitions for Cs₂NaLnCl₆ DPs NCs. Ce^{III}, Pr^{III}, and Tb^{III} clearly featured 4f→5d transitions at 4.16, 5.16, and 2.47 eV, respectively, while Sm^{III}, Eu^{III}, and Yb^{III} featured Cl 3p to Ln 4f LMCT transitions at 2.48, 1.59, and 2.66 eV, respectively. Even with the observed discrepancies in transition energies, TD-DFT was able to correctly predict the lowest energy allowed electronic transitions of all six Ln-DP NCs showing features in the UV-vis spectrum. The calculated transition energies differed significantly from experimentally obtained results, highlighting the challenges and limitations in the calculation of lanthanide 4f electronic states.

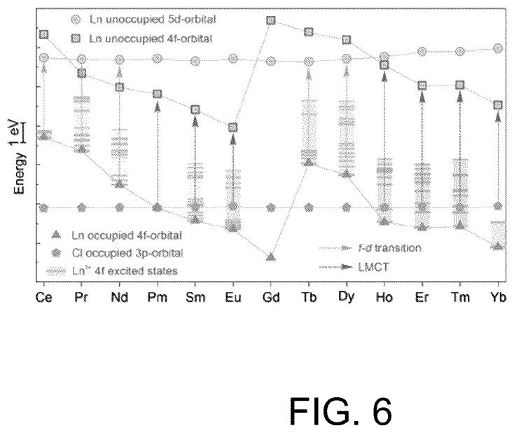

With both experimental and computational data in hand, we set out to construct a semi-empirical energy diagram capable of summarizing the electronic structure and optical properties of Cs₂NaLnCl₆ DP NCs. In order to construct a diagram with relative orbital energies of sufficient accuracy, the highest occupied and unoccupied 4f orbital energies were corrected by using experimentally determined values for the lowest energy 4f→5d or LMCT transitions, where Cl 3p and Ln 5d orbital energies were taken from DFT calculations of the molecular analogs, [Na₃LnCl₆]³⁺. LMCT transitions were used to adjust the DFT-calculated energies of unoccupied 4f orbitals relative to Cl 3p orbitals, while 4f→5d transitions were used to correct occupied 4f orbital energies with respect to Ln 5d orbitals. Select sections of the excited Ln^{III} 4f manifold were constructed using previously reported, 4f orbital energies experimentally determined for bulk Cs₂NaLnCl₆ (FIG. 6). F. S. Richardson, et al., J. Chem. Phys. 1998, 83, 3813. Based on the diagram, the lowest energy absorptions for the Ln with filled 4f-orbital energies above that of the C1 3p-orbitals (the cases of Ce, Pr, Nd, Tb, and Dy) were predicted to be dominated by the f→d atomic transitions (FIG. 6, red dashed line arrows). The f→d transition energies increased with rising Ln^{III/IV} redox potential (Ce<Pr≈Tb<Dy) as expected and discussed above (FIGS. 4 and 5). J. L. Ryan, et al., J. Phys. Chem. 1966, 70, 2845. In contrast, the first absorption feature of Ln with filled 4f-orbitals below the Cl 3p-orbital energy levels should be dominated by LMCT transitions, as for the cases of Sm, Eu, Gd, Ho, Er, Tm, and Yb (FIG. 6). The corresponding LMCT transition energies (FIG. 6, blue dashed line arrows) agreed reasonably well with the Ln^{II/III} redox potential (Eu<Yb≈Sm<Tm). J. L. Ryan, et al., J. Phys. Chem. 1966, 70, 2845. The suitability of this semi-empirical model was further validated by comparing the relative orbital energies with experimentally determined values from valence band XPS spectra for the selected Cs₂NaLnCl₆ (Ln=Ce, Pr, Tb, and Gd). Energy differences between the filled Cl 3p_{3/2} and Ln 4f orbitals measured by XPS were in good agreement with the corrected values constructed in the semi-empirical model, and provided further support for our model.

Alloyed Ln-DP NCs with Enhanced Optical Properties

Alloying and doping have been used extensively in the past to enhance optical properties of NCs, as alloyed nanomaterials can deliver properties inaccessible to physical mixtures of different components. G. Pan, et al., Nano Lett. 2017, 17, 8005. The successful synthesis of alloyed perovskite materials can be challenging, as stable combinations require appropriate matching of the introduced cation's size with the host material's tolerance factor while keeping charge balance in mind. Z. Li, et al., Chem. Mater. 2016, 28, 284. Given the similar ionic radii of Ln^{III} ions, R. D. Shannon, Acta Crystallogr., Sect. A: Found. Adv. 1976, 32, 751, a large range of alloyed DP NCs should be accessible. To demonstrate this possibility, two representative examples of alloyed Cs₂NaLnCl₆ DP NCs were synthesized.

Cs₂NaCe_{0.90}Tb_{0.09}Yb_{0.01}Cl₆ DP NCs

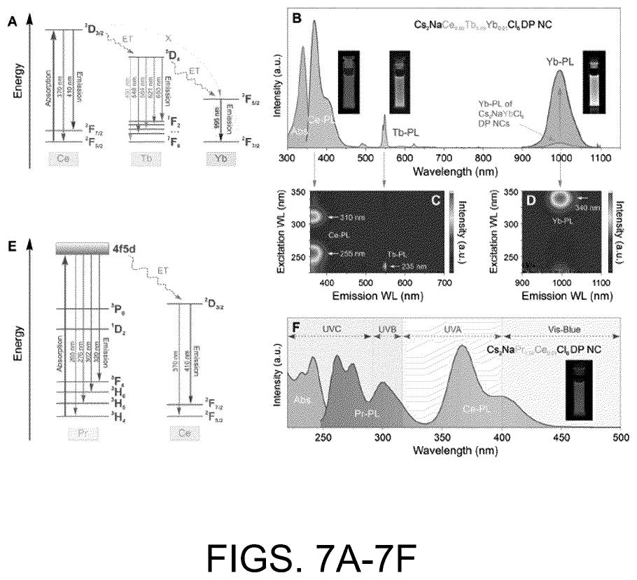

Ternary alloys showing emission across the UV, visible, and NIR range are interesting synthetic targets for light emission purposes, for multiplex imaging in biological setups, or for the synthesis of advanced anti-counterfeit materials. [J. Eng, et al., Commun. Biol. 2022, 5, 438] Using the hot injection methodology described for Ln-pure DP NCs, Cs₂NaCe_{0.90}Tb_{0.09}Yb_{0.01}Cl₆ alloyed Ln-DP NCs were successfully synthesized. Under 340 nm excitation, the Cs₂NaCe_{0.90}Tb_{0.09}Yb_{0.01}Cl₆ DP NCs displayed PL peaks from all three Ln components: Ce^{III} emission at 365 nm, Tb^{III} emission at 550 nm, and Yb^{III} emission at 995 nm (FIG. 7A,B). Importantly, the NIR Yb-PL peak at 995 nm was significantly increased in intensity as compared to the pure Cs₂NaYbCl₆ DP NCs (FIG. 7B). The PLQY in the NIR range (i.e., Yb-PL) was determined to be 6%, indicating a ≈30-fold enhancement as compared to that of the pure Cs₂NaYbCl₆ DP NCs (FIG. 7B). This enhancement effect was significantly diminished if the Tb “bridge” was omitted, evidenced by a much lower NIR PLQY of ≈1% for the Cs₂NaCe_{0.99}Yb_{0.01}Cl₆ DP NCs synthesized analogously. Furthermore, the alloyed Cs₂NaCe_{0.90}Tb_{0.09}Yb_{0.01}Cl₆ Ln-DP NCs also showed an excitation-dependent luminescence property. The peak intensities of both visible (FIG. 7C) and NIR (FIG. 7D) emissions changed dramatically depending on the excitation wavelength, which cannot be seen when individual Ln-pure Cs₂NaLnCl₆ (Ln=Ce, Tb, and Yb) NCs are mixed with the appropriate ratio. The Ce-PL can be sensitized by the excitation light with two wavelengths in comparable intensities: 255 and 310 nm. While the strongest Tb— PL can only be observed under 235 nm excitation, the strongest Yb-PL is displayed only when exciting at 340 nm (FIG. 7D).

Cs₂NaPr_{0.99}Ce_{0.01}Cl₆ DP NCs

UV-emissive perovskite nanomaterials are exceedingly rare and highly sought after, and such materials hold the potential to be utilized in biomedical settings as disinfecting light sources, (F. Chiappa, et al., J. Hosp. Infect. 2021, 114, 63) or in fabrications of high-energy LEDs as the UV-emissive component. Y. Muramoto, et al., Semicond. Sci. Technol. 2014, 29, 084004. Given our discovery of Cs₂NaCeCl₆ and Cs₂NaPrCl₆ DP NCs capable of emitting in the UV-C and UV-A region, we synthesized Cs₂NaPr_{0.99}Ce_{0.01}Cl₆ DP NCs using an appropriate mixture of Ce(OAc)₃ and Pr(OAc)₃ precursors. The obtained Cs₂NaPr_{0.99}Ce_{0.01}Cl₆ DP NCs emit across the UV-C to UV-A, and into the visible blue spectral range, representing the first example of a broad UV-emitting perovskite nanomaterial (FIG. 7E,F).

In summary, we demonstrate the colloidal synthesis of Cs₂NaLnCl₆ (Ln=La—Nd, Sm—Yb) Ln-DP NCs using a hot injection approach. The obtained Ln-DP NCs display emissions covering a wide wavelength range from deep UV to NIR. The Cs₂NaPrCl₆ and Cs₂NaCeCl₆ DP NCs display strong UV emission, with the Cs₂NaPrCl₆ DP NCs being the only UV-C emitting halide perovskite nanomaterial known to date. Using the combination of molecular analogs and DFT calculations, a comprehensive understanding of energy levels and electronic transitions in the Cs₂NaLnCl₆ DP systems was achieved. Due to the similar ionic sizes and high miscibility of Ln elements, we have successfully synthesized alloyed Ln-DP NCs simultaneously containing multiple Ln components, which show unique optical properties that are inaccessible by their pure-Ln counterparts. Our study not only provides important fundamental understandings on the Ln-DP materials, but also offers a family of new DP nanomaterials promising for a spectrum of applications ranging from high-energy LEDs and secure anti-counterfeiting paints to biomedical disinfections.

### Experimental Procedures

### Chemicals

Cesium carbonate (99.9%), sodium acetate (anhydrous, ≥99%), cerium acetylacetonate hydrate, cerium acetate hydrate (99.9%), terbium acetate hydrate (99.9%), erbium acetate hydrate (99.9%), thulium acetate hydrate (99.9%), ytterbium acetate tetrahydrate (99.9%), chlorotrimethylsilane (TMS-Cl, ≥99%), 1-octadecene (ODE, technical grade 90%), oleylamine (OAm, technical grade 70%) and oleic acid (OA, technical grade 90%) were purchased from Aldrich. Lanthanum acetate sesquihydrate (99.9%), praseodymium acetate hydrate (99.9%) and europium acetate hydrate (99.9%) were purchased from Alfa Aesar. Neodymium acetate hydrate (99.9%), samarium acetate hydrate (99.9%), gadolinium acetate tetrahydrate (99.9%), dysprosium acetate hydrate (99.9%) and holmium acetate monohydrate (99.9%) were obtained from Strem Chemicals. Hexane, ethyl acetate and toluene for use in ambient air were obtained from Fisher. Hexane (anhydrous), ethyl acetate (anhydrous) and toluene (anhydrous) used in the glovebox were obtained from Aldrich. All chemicals were used as received without further purification.

### Syntheses

Cs₂NaLaCl₆ Double Perovskite (DP) Nanocrystals (NCs):

Cesium carbonate (53 mg, 0.16 mmol), sodium acetate (18 mg, 0.22 mmol) and lanthanum acetate sesquihydrate (85 mg, 0.25 mmol) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-based DP (Ln-DP) NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaCeCl₆ DP NCs:

Cesium carbonate (53 mg, 0.16 mmol), sodium acetate (18 mg, 0.22 mmol) and cerium acetylacetonate hydrate (105 mg, 0.25 mmol—anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox. The synthesis can be carried out using an equimolar amount of cerium(III) acetate hydrate instead of cerium(III) acetylacetonate hydrate as well.

Cs₂NaPrCl₆ DP NCs:

Cesium carbonate (53 mg, 0.16 mmol), sodium acetate (18 mg, 0.22 mmol) and praseodymium acetate hydrate (85 mg, 0.27 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaNdCl₆ DP NCs:

Cesium carbonate (53 mg, 0.16 mmol), sodium acetate (18 mg, 0.22 mmol) and neodymium acetate hydrate (80 mg, 0.25 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaSmCl₆ DP NCs:

Cesium carbonate (53 mg, 0.16 mmol), sodium acetate (18 mg, 0.22 mmol) and samarium acetate hydrate (82 mg, 0.25 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaEuCl₆ DP NCs:

Cesium carbonate (53 mg, 0.16 mmol), sodium acetate (18 mg, 0.22 mmol) and europium acetate hydrate (82 mg, 0.25 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaGdCl₆ DP NCs:

Cesium carbonate (37 mg, 0.11 mmol), sodium acetate (18 mg, 0.22 mmol) and gadolinium acetate tetrahydrate (101 mg, 0.25 mmol) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaTbCl₆ DP NCs:

Cesium carbonate (53 mg, 0.16 mmol), sodium acetate (18 mg, 0.22 mmol) and terbium acetate hydrate (84 mg, 0.25 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaDyCl₆ DP NCs:

Cesium carbonate (53 mg, 0.16 mmol), sodium acetate (18 mg, 0.22 mmol) and dysprosium acetate hydrate (90 mg, 0.27 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaHoCl₆ DP NCs:

Cesium carbonate (37 mg, 0.11 mmol), sodium acetate (18 mg, 0.22 mmol) and holmium acetate monohydrate (90 mg, 0.25 mmol) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaErCl₆ DP NCs:

Cesium carbonate (53 mg, 0.16 mmol), sodium acetate (18 mg, 0.22 mmol) and erbium acetate hydrate (86 mg, 0.25 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaTmCl₆ DP NCs:

Cesium carbonate (53 mg, 0.16 mmol), sodium acetate (18 mg, 0.22 mmol) and thulium acetate hydrate (86 mg, 0.25 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaYbCl₆ DP NCs:

Cesium carbonate (53 mg, 0.16 mmol), sodium acetate (18 mg, 0.22 mmol) and ytterbium acetate tetrahydrate (105 mg, 0.25 mmol) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMSCl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs₂NaPr_{0.99}Ce_{0.01}Cl₆ DP NCs:

Cesium carbonate (53 mg, 0.16 mmol), sodium acetate (18 mg, 0.22 mmol) cerium acetate hydrate (1.5 mg, 4 μmol, anhydrous basis), praseodymium acetate hydrate (80 mg, 0.25 mmol, anhydrous basis) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox.

Cs2NaCe0.90Tb0.09Yb0.01Cl₆ DP NCs: Cesium carbonate (53 mg, 0.16 mmol), sodium acetate (18 mg, 0.22 mmol) cerium acetate hydrate (75 mg, 0.22 mmol—anhydrous basis), terbium acetate hydrate (9 mg, 30 μmol, anhydrous basis) and ytterbium acetate tetrahydrate (1.5 mg, 4 μmol) were added to ODE (5.0 mL). To this suspension, OA (1.25 mL) and OAm (330 μL) were added with stirring. The mixture was degassed under vacuum at 110° C. for one hour, after which the mixture was heated to 180° C. under nitrogen. TMS-Cl (200 μL, 1.58 mmol) was injected at once and the temperature was kept between 180° C.±2° C. for two minutes. The reaction was then quenched with ice water and the particles were isolated by centrifugation at 6000 RPM for 10 minutes, discarding the liquid phase. The obtained Ln-DP NC solids were redispersed in hexane (4 mL) and the suspension was centrifuged at 7000 RPM for 5 minutes. The precipitates were discarded, and ethyl acetate (10 mL) was added to the liquid phase. The mixture was then centrifuged again at 7000 RPM for 10 minutes, followed by discarding the supernatant. The precipitated DP NCs were then dispersed in hexane (3 mL) and the suspension was centrifuged one final time at 7000 RPM for 5 minutes, followed by discarding the precipitates. The resulting NC hexane suspension can be stored under dry air protection or inside a glovebox. Cs₂NaCe_{0.99}Yb_{0.01}Cl₆ DP NCs were synthesized using the same procedure by adjusting the molar ratio of Ce to Yb in the starting mixture appropriately.

NC Storage

While Ln-DP NCs were found to be stable towards oxygen, some moisture-sensitivity was noted. For storage, Ln-DP NC suspensions in hexane were added to glass vials, which were sealed under a gentle flow of dry compressed air or nitrogen. The particles can be stored this way for at least 4 weeks in air. Alternatively, the particle suspensions can be stored under inert conditions inside a drybox for extended periods of time.

Ultraviolet-Visible (UV-Vis) Absorption Spectroscopy Measurements

Absorption spectra were collected using an Agilent Cary 8454 UV-Vis Spectrometer. Samples were dispersed in hexane for the measurement and spectra were collected in ambient air. f-f absorption spectra of Cs₂NaYbCl₆ DP NCs were collected using a Varian Cary 50 Bio spectrometer.

Photoluminescence (PL), PL Excitation (PLE) Spectroscopy and PL Quantum Yield (PLOY) Measurements

PL and PLE spectra were measured using an Edinburgh Instruments FS5 Spectrofluorometer. NCs were dispersed in hexane and PL spectra were collected while irradiating the samples at the first absorption peak wavelength. All PLE measurements were carried out monitoring PL intensity at the PL peak wavelengths. PLQYs were determined using a built-in integrating sphere on the Edinburgh Instruments FS5 Spectrofluorometer. The detectors used for measuring the PL include a visible range signal detector (a UV enhanced silicon photodiode) with spectral coverage from 200 nm to 870 nm and a NIR signal detector (a thermoelectric cooled InGaAs photodiode) with spectral coverage from 850 nm to 1650 nm. The full PL spectra were obtained by connecting two spectra collected by the visible signal detector and NIR signal detector with a scaling factor using CuInS2/ZnS core/shell nanocrystal (emitting at 880 nm with a peak width of ˜170 nm) solution as a calibration sample for the responsivity of the two detectors under the same measurement conditions. All measurements were collected in ambient air.

X-Ray Diffraction (XRD) Measurements

Powder XRD patterns were obtained on a Bruker D8 Discovery 2D X-ray Diffractometer equipped with a Vantec 500 2D area detector working on Cu Kα radiation. NC samples were drop-cast on a glass slide inside the glovebox followed by slow evaporation of the solvent. The glass slides were then sealed in air-tight containers under nitrogen and the samples were transported to the XRD machine. The XRD spectra were collected in air over the course of ˜10 minutes to avoid absorption of moisture.

Transmission Electron Microscopy (TEM) and High-Resolution TEM (HR-TEM) Measurements

TEM measurements were carried out using a JEOL-2100F TEM operating at 200 kV. Samples were drop-cast on a 300-mesh TEM grid and allowed to dry under nitrogen inside the glovebox. The grids were then sealed in air-tight containers under nitrogen and the samples were transported to the electron microscope. The grids were quickly mounted in air to minimize moisture exposure.

X-Ray Photoelectron Spectroscopy (XPS) Measurements

XPS spectra were measured on a Thermo Scientific KAlpha+ instrument operating on Al K_{α}=1486.6 eV radiation with a spot size of 400 μm. Samples dispersions were drop-casted on silicon wafers and allowed to evaporate with gentle heating. The samples were transported to the XPS machine under vacuum using a Thermo Scientific 831-57-100-2 vacuum transfer vessel. All XPS spectra were calibrated by setting the adventitious carbon is signal to 284.8 eV. Samples were ion etched using Ar+ ions for 30 seconds before data collection unless otherwise indicated.

The complete disclosure of all patents, patent applications, and publications, and electronically available materials cited herein are incorporated by reference. The foregoing detailed description and examples have been given for clarity of understanding only. No unnecessary limitations are to be understood therefrom. The invention is not limited to the exact details shown and described, for variations obvious to one skilled in the art will be included within the invention defined by the claims.

What is claimed is:

1. Double perovskite nanocrystals represented by the formula Cs₂ABX₆, wherein:
A is an alkali metal;
B is one or more lanthanide selected from the group consisting of La, Ce, Pr, Nd, Sm, Eu, Gd, Tb, Dy, Ho, Er, Tm, and Yb; and
X is a halide selected from Br, Cl, or I.

2. The double perovskite nanomaterial of claim 1, wherein X is Cl.

3. The double perovskite nanomaterial of claim 1, wherein the alkali metal is Na.

4. The double perovskite nanomaterial of claim 1, wherein the nanocrystals have a cuboid morphology and an edge length from about 5 to about 20 nm.

5. The double perovskite nanomaterial of claim 4, wherein the edge length is from about 7.5 to about 15 nm.

6. The double perovskite nanomaterial of claim 1, wherein the nanomaterial is an alloy comprising a plurality of lanthanides.

7. A light emitting material comprising a material comprising double perovskite nanocrystals represented by the formula Cs₂ABX₆, wherein:
A is an alkali metal;
B is one or more lanthanide selected from the group consisting of La, Ce, Pr, Nd, Sm, Eu, Gd, Tb, Dy, Ho, Er, Tm, and Yb; and
X is a halide selected from Br, Cl, or I.

8. The light emitting material of claim 7, wherein the material luminesces at a wavelength ranging from 260 to 1550 nm.

9. The light emitting material of claim 7, wherein B is Pr, and the material has a peak emission from about 260 nm to about 270 nm.

10. The light emitting material of claim 7, wherein B is Tb, and the material has a peak emission from about 540 nm to about 560 nm.

11. The light emitting material of claim 7, wherein B is Sm, and the material has a peak emission from about 590 nm to about 610 nm.

12. The light emitting material of claim 7, wherein B is Yb, and the material has a peak emission from about 990 nm to about 1000 nm.

13. The light emitting material of claim 7, wherein B is Eu, and the material has a peak emission from about 600 nm to about 620 nm.

14. The light emitting material of claim 7, wherein the double perovskite nanocrystals are alloys comprising a plurality of lanthanides.

15. A light emitting device comprising a light emitting material comprising double perovskite nanocrystals represented by the formula Cs₂ABX₆, wherein:
A is an alkali metal;
B is one or more lanthanide selected from the group consisting of La, Ce, Pr, Nd, Sm, Eu, Gd, Tb, Dy, Ho, Er, Tm, and Yb; and
X is a halide selected from Br, Cl, or I.

16. The light emitting device of claim 15, wherein the device is a light emitting diode.

17. The light emitting device of claim 15, wherein the device is a solar concentrator.

18. The light emitting device of claim 15, wherein the device is a laser.

19. The light emitting device of claim 15, wherein the double perovskite nanocrystals are alloys comprising a plurality of lanthanides.

20. A method of preparing double perovskite nanocrystals represented by the formula Cs₂ABX₆, wherein:
A is an alkali metal;
B is one or more lanthanide selected from the group consisting of La, Ce, Pr, Nd, Sm, Eu, Gd, Tb, Dy, Ho, Er, Tm, and Yb; and
X is a halide selected from Br, Cl, or I;
comprising the steps of:
1) adding cesium salt, an alkali metal salt, and a lanthanide salt or acetylacetonate to a mixture of a non-polar organic solvent, oleic acid, and oleylamine;
2) degassing the mixture for about 30 minutes to about 2 hours at a temperature ranging from about 60° C. to about 120° C. to remove oxygen and water;
3) injecting chloromethylsilane at a temperature from about 150° C. to about 200° C.;
4) rapidly cooling the mixture to about room temperature; and
5) collecting double perovskite nanocrystals from the mixture.

21. The method of claim 20, wherein the non-polar organic solvent is octadecene.

22. The method of claim 20, wherein the cesium salt is cesium carbonate.

23. The method of claim 20, wherein the alkali metal salt is alkali metal acetate, and the lanthanide salt is lanthanide acetate.

24. The method of claim 20, wherein the step of degassing the mixture is carried out for about one hour at about 110° C.

25. The method of claim 20, wherein the chloromethylsilane is injected at about 180° C.

26. The method of claim 20, wherein B comprises a plurality of different lanthanides to provide a double perovskite nanocrystal alloy.
